(19) United States
(12) Patent Application Publication
(10) Pub. No.: US 2006/0213641 A1
(43) Pub. Date: Sep. 28, 2006

(54) Heat sink

(75) Inventor: Yen-Hsun Chou, Taoyuan County (TW)

Correspondence Address: BROWDY AND NEIMARK, P.L.L.C.;624 NINTH STREET, NW, SUITE 300, WASHINGTON, DC, 20001-5303, US

(73) Assignee: Yuh-Cheng Chemical Ltd., Taipei City (TW)

(21) Appl. No.: 11/088,845

(22) Filed: Mar. 25, 2005

(51) Int. Cl. H05K 7/20

(52) U.S. Cl. 165/80.3; 361/704

(57) ABSTRACT

A heat sink includes a plurality of plate members stacked one by one. The plate member has a plurality of mounting holes at the body thereof and a plurality of bottom mounting lugs each having a through hole such that the mounting lug is elastically deformable. The bottom mounting lugs of one metal plate member can be elastically deformed and inserted into the mounting holes of another metal plate member to have the metal plate members be secured together.

### BACKGROUND OF THE INVENTION

1. Field of the Invention

The present invention relates to a heat sink for dissipating heat from a heat source and more particularly, to such a heat sink, which has a steady structure and is easy to assemble.

2. Description of the Related Art

A conventional heat sink 1, as shown in FIG. 1, comprises a plurality of metal plate members 2 arranged in a stack. Each metal plate member 2 comprises a plurality of mounting holes 4 and a plurality of mounting lugs 3. Each mounting lug 3 has a base 5 and two arms 6 at two sides of the base 5. During installation, the mounting lugs 3 of one metal plate member 2 are respectively inserted into the mounting holes 4 of another metal plate member 2, and then the arms 6 of the mounting lugs 3 are hammered down, thereby securing the respective mounting lugs 3 to the respective mounting holes 4. This heat sink assembly process requires much time and labor, resulting in a high manufacturing cost.

### SUMMARY OF THE INVENTION

The present invention has been accomplished under the circumstances in view. It is one objective of the present invention to provide a heat sink, which has a steady structure and is easy to assemble.

To achieve this objective of the present invention, the heat sink provided by the present invention comprises a plurality of plate members stacked together. The plate member has a rectangular body having a mounting hole, a first sidewall extending from a first side of the rectangular body, a second sidewall extending from a second side of the rectangular body, and a mounting lug extending from a bottom side of the first sidewall in such a manner that the mounting lug of one plate member is insertable into the mounting hole of another plate member to secure the plate members in a stack. The mounting lug has a through hole so that the mounting lug is elastically deformable when it is pressed.

### BRIEF DESCRIPTION OF THE DRAWINGS

FIG. 1 is a perspective view of a heat sink according to the prior art.

FIG. 2 is an exploded front view of the heat sink according to the present invention.

FIG. 3 is a front view of a plate member for heat sink according to the present invention.

FIG. 4 is a top view of a plate member for heat sink according to the present invention.

FIG. 5 is a schematic side view of a part of the present invention.

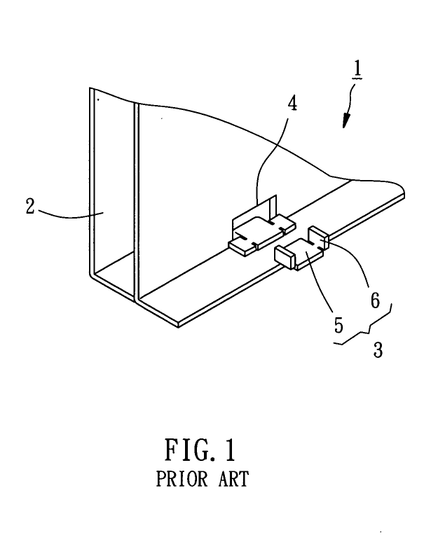

### DETAILED DESCRIPTION OF THE INVENTION

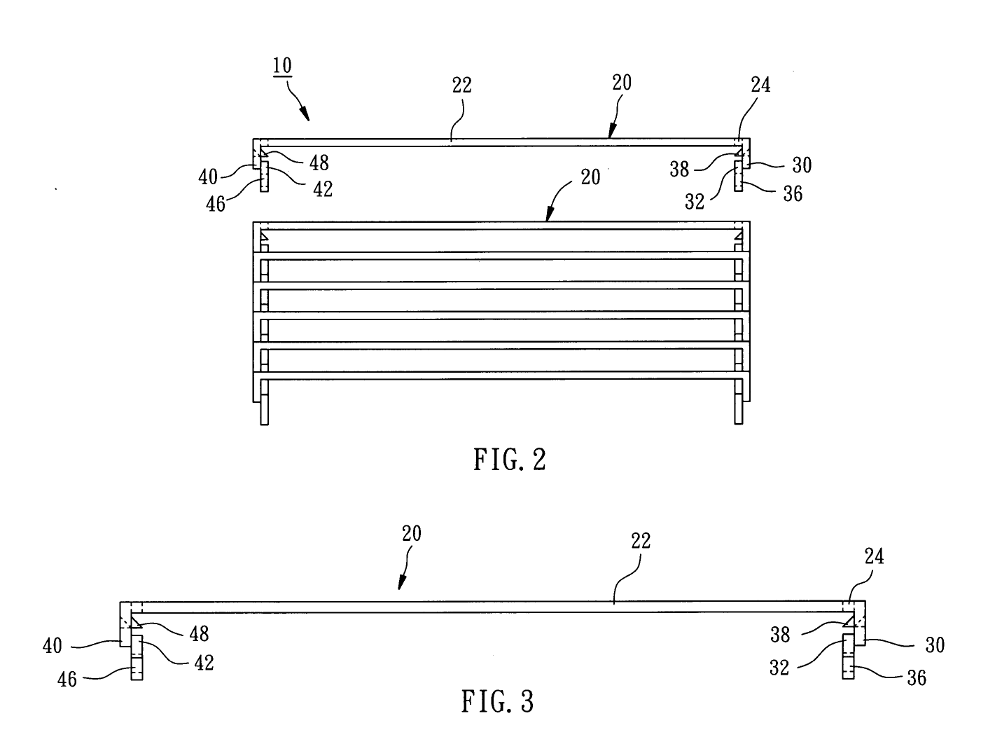

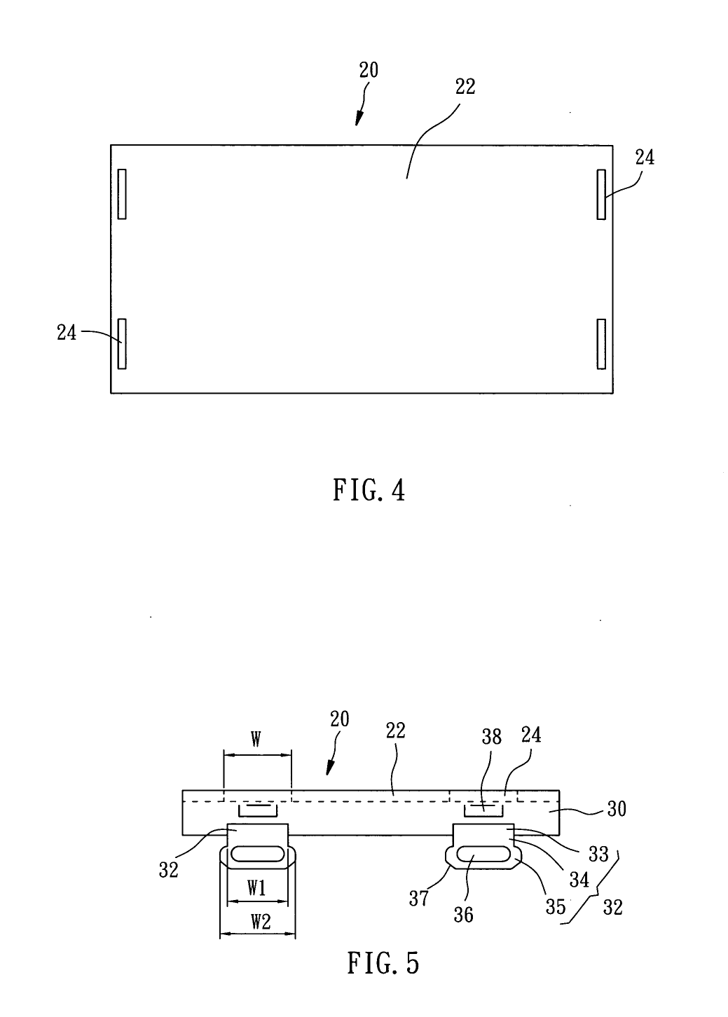

Referring to FIGS. 2-5, a heat sink 10 in accordance with the present invention is shown comprised of a plurality of plate members 20 arranged in a stack. The plate members 20 are made of metal material, for example, copper or aluminum. Each plate member 20 has a rectangular body 22, and two parallel sidewalls, namely, the first sidewall 30 and the second sidewall 40 respectively perpendicularly extending from two opposite short sides, namely, the first and the second sides, of the rectangular body 22 in same direction.

The rectangular body 22 has four mounting holes 24 symmetrically disposed near the two short sides and extending through the top and bottom surfaces.

The first sidewall 30 comprises two bottom mounting lugs 32 for engaging into the two mounting holes 24 near one short side of the rectangular body 22 of another plate member 20. Each bottom mounting lug 32 comprises a base 33 connected to the bottom side of the first sidewall 30, a head 35, and a neck 34 connected between the base 33 and the head 35. The width W1 of the neck 34 is shorter than the width W of the mounting holes 24. The width W2 of the head 35 is greater than the width W of the mounting holes 24. The head 35 has an oval through hole 36, and two chamfered edges 37 that facilitate insertion of the mounting lug 32 into one mounting hole 24. The first sidewall 30 further comprises two inwardly protruded hooked members 38 for hooking in the oval through holes 36 of the mounting lugs 32 of the first sidewall 30 of another plate member 20. When hooked, each inwardly protruded hooked member 38 is stopped at the bottom edge of the respective oval through hole 36.

The second sidewall 40 comprises two bottom mounting lugs 42 and two inwardly protruded hooked members 48. Similar to the bottom mounting lugs 32 of the first sidewall 30, each bottom mounting lug 42 of the second sidewall 40 comprises a base 43, a head 45 with an oval through hole 46 and two chamfered edges 47, and a neck 44 connected between the base 43 and the head 45.

Because the width W2 of the head 35 or 45 is greater than the width W of the mounting holes 24, the head 35 or 45 of the mounting lug 32 or 42 must be elastically deformed so that the mounting lug 32 or 42 can be inserted through the respective mounting hole 24. The oval through hole 36 or 46 allows the required elastic deformation of the head 35 or 45. After insertion through the mounting hole 24, the head 35 or 45 immediately returns to its former shape to hold the neck 34 or 44 in the mounting hole 24. Therefore, the respective mounting lugs 32 and 42 can be positively secured to the respective mounting holes 24, holding two plate members 20 together.

Further, after hooking of the respective inwardly protruded hooked member 38 or 48 in the respective oval through hole 36 or 46, each inwardly protruded hooked member 38 or 48 is stopped against the bottom edge of the respective oval through hole 36 or 46, reinforcing the connection between the two plate members 20. Simply by inserting the respective mounting lugs 32 and 42 into the respective mounting holes 24 with a small pressure, multiple plate members 20 are quickly assembled.

Although a particular embodiment of the invention has been described in detail for purposes of illustration, various modifications and enhancements may be made without departing from the spirit and scope of the invention. For example, the first sidewall and the second sidewall may be respectively perpendicularly extending from two adjacent sides of the body; the number and shape of the mounting lugs and the inwardly protruded hooked members may be varied. Accordingly, the invention is not to be limited except as by the appended claims.

What is claimed is:

1. A heat sink comprising:
a plurality of plate members arranged in a stack, each said plate member having a rectangular body having a mounting hole, a first sidewall extending from a first side of said rectangular body, a second sidewall extending from a second side of said rectangular body, and a mounting lug extending from a bottom side of said first sidewall in such a manner that the mounting lug of one said plate member is insertable into the mounting hole of another said plate member to secure said plate members in a stack, said mounting lug having a through hole.

2. The heat sink as claimed in claim 1, wherein said mounting lug comprises a base connected to the bottom side of said first sidewall of the plate member, a head having said through hole, and a neck connected between said base and said head, said neck having a width smaller than the width of said mounting hole, said head having a width greater than the width of said mounting hole.

3. The heat sink as claimed in claim 2, wherein said head has two chamfered bottom edges at two sides.

4. The heat sink as claimed in claim 1, wherein each said plate member further comprises a hooked member provided at said first sidewall such that the hooked member of one said plate member is engageable into the through hole of the mounting lug of another said plate member.

5. The heat sink as claimed in claim 4, wherein said hooked member is stopped against a bottom edge of the through hole into which said hooked member is engaged.

6. A heat sink comprising:
a plurality of metal plate members stacked one by one;
wherein the metal plate member comprises a body having a plurality of mounting holes, a first side wall extending from a first side of the body, a second side wall extending from a second side of the body, and a plurality of mounting lugs respectively extending from bottom sides of the first and second side walls, each said mounting lug having a through hole such that said mounting lug is elastically deformable when said mounting lug is pressed;
wherein said mounting lugs of one said plate member are respectively inserted into said mounting holes of another said plate member to have said plate members be secured together.

7. The heat sink as claimed in claim 6, wherein said mounting lugs each comprise a base respectively connected to the bottom sides of said first and second sidewalls of the plate member, a head having said through hole, and a neck connected between said base and said head; wherein said necks have a width smaller than the width of said mounting holes and said heads have a width greater than the width of said mounting holes.

8. The heat sink as claimed in claim 7, wherein said heads each have two chamfered bottom edges at two sides thereof.

9. The heat sink as claimed in claim 6, wherein each said plate member further comprises a plurality of hooked members respectively inwardly protruded from said first sidewall and said second sidewall such that the hooked members of one said plate member are engageable into the through holes of the mounting lugs of another said plate member.
